(19) United States
(12) Patent Application Publication
(10) Pub. No.: US 2019/0237400 A1
(43) Pub. Date: Aug. 1, 2019

(54) INTEGRATED CIRCUIT WITH METALLIC INTERLOCKING STRUCTURE

(71) Applicant: HRL Laboratories, LLC, Malibu, CA (US)

(72) Inventors: Florian G HERRAULT, Agoura Hills, CA (US); Joel C. Wong, Los Angeles, CA (US); Helen Hor Ka. Fung, Los Angeles, CA (US); Partia Naghibi-Mahmoudabadi, Los Angeles, CA (US)

(73) Assignee: HRL Laboratories, LLC, Malibu, CA (US)

(21) Appl. No.: 16/213,709

(22) Filed: Dec. 7, 2018

Related U.S. Application Data
(60) Provisional application No. 62/625,313, filed on Feb. 1, 2018.

(51) Int. Cl. H01L 23/522; H01L 23/495; H01L 21/768; H01L 21/74; H01L 23/535

(52) U.S. Cl. CPC H01L 23/5226; H01L 23/49582; H01L 23/535; H01L 21/743; H01L 21/76898

(57) ABSTRACT

An integrated component having a metallic interlocking structure; the integrated component comprising an integrated circuit integrated in a substrate having a top surface; the integrated circuit comprising a first conducting line; and a first metallic interlocking structure comprising a first array of free-standing metallic columns formed on said top surface and electrically connected to said first conducting line.

### RELATED APPLICATION

The present application claims priority of U.S. provisional application No. 62/625,313, filed on Feb. 1, 2018 and entitled “INTEGRATED CIRCUIT WITH METALLIC INTERLOCKING STRUCTURE”, which is hereby incorporated by reference.

### TECHNICAL FIELD

This presentation relates to integrated components, and in particular to an integrated component that comprises both an integrated circuit and a metallic interlocking structure that allows removably connecting the integrated circuit. This presentation also relates to a method of manufacturing such integrated component having a metallic interlocking structure. This presentation also relates to an integrated component assembly comprising two such integrated components removably connected together by their interlocking structures.

### BACKGROUND

High-performance electrical and mechanical contacts and interconnects are highly desirable for system-level integration of multiple semiconductor components and technologies in 3D integration technologies (such as wafer-to-wafer bonding or die-to-wafer assembly). However, the state-of-the-art bonding technologies typically require processes based on heat and/or pressure and are not re-workable (meaning that a bond is permanent, and cannot be reworked if damaged).

It is known to use interlocking structures to temporarily assemble a discrete electronic component on a printed circuit board, for example by providing the printed circuit board with a socket that interlocks with the pins of the electronic components and connects electrically the pins to the printed circuit boards. Such known structures can use spring or bump contacts, or can use the resiliency of the pins they interlock with to create temporary electrical contact structures. However, all known interlocking structures suitable for temporary connections are relatively large structures that require to be manufactured separately, then assembled to some electronic components to allow connecting temporarily said electronic components to other electronic components having complementary interlocking structures. For example, known interlocking structures comprise a pin grid array IC package that can be assembled to an IC, where the pin grid array package allows connecting temporarily the IC to other ICs mounted on a board equipped with a pin grid array socket.

Some known silicon-etched microstructures form MEMS “hook and loop” structures. However, such structures only allow a single assembly and they do not allow removably connecting integrated circuits. Other known means that create room temperature bonding require smashing contacts together to create a good electrical contact but the resulting bond cannot be undone without destroying one or both components.

### REFERENCES

[1] U.S. Pat. No. 6,543,131B1—Microelectronic joining processes with temporary securement.
[2] U.S. Pat. No. 6,329,829B1—Interconnect and system for making temporary electrical connections to semiconductor components.
[3] U.S. Pat. No. 6,913,476B2—Temporary, conformable contacts for microelectronic components.
[4] S. Khumpuang, A. Ohtomo, N. Shibayama, K. Miyake and T. Itoh, “Novel conductive polymer micro-spring contact array for large area woven electronic textile,” 2011 IEEE 24th International Conference on Micro Electro Mechanical Systems, Cancun, 2011, pp. 296-299.—Conductive polymer contacts.
[5] E. M. Chow, C. Chua, T. Hantschel, K. Van Schuylenbergh and D. K. Fork, “Pressure Contact Micro-Springs in Small Pitch Flip-Chip Packages,” in IEEE Transactions on Components and Packaging Technologies, vol. 29, no. 4, pp. 796-803, December 2006.—Spring contacts.
[6] S. van Bracht, G. Semon, J. L. Herder and N. Tolou, “Compliant continuous-locking micro mechanism,” 2016 International Conference on Manipulation, Automation and Robotics at Small Scales (MARSS), Paris, 2016, pp. 1-7.—Comb-finger spring lock mechanism.
[7] B. Cheng et al., “Microspring Characterization and Flip-Chip Assembly Reliability,” in IEEE Transactions on Components, Packaging and Manufacturing Technology, vol. 3, no. 2, pp. 187-196, February 2013.—Microspring contacts reliability.
[8] K. Kataoka, S. Kawamura, T. Itoh, T. Suga, K. Ishikawa and H. Honma, “Low contact-force and compliant MEMS probe card utilizing fritting contact,” Technical Digest. MEMS 2002 IEEE International Conference. Fifteenth IEEE International Conference on Micro Electro Mechanical Systems (Cat. No. 02CH37266), Las Vegas, Nev., USA, 2002, pp. 364-367.—Fritting contact.
[9] Itoh, T., Kawamura, S., Suga, T., Kataoka, K., “Development of an electrostatically actuated MEMS switching probe card,” Proceedings of the 50th IEEE Holm Conference on Electrical Contacts and the 22nd International Conference on Electrical Contacts, Seattle, Wash., 2004, pp. 226-230.—Electrostatically actuated contacts.
[10] E. M. Chow, K. Klein, D. K. Fork, T. Hantschel, C. L. Chua, L. Wong and K. Van Schuylenbergh, “Intermittency study of a stressed-metal micro-spring sliding electrical contact” Proceedings of the 53^{rd} Electronic Components and Technology Conference, New Orleans, La., 2003, pp. 1714-1717.—Sliding spring contact.
[11] J. Haemer, J. M., Sitaraman, S. K., Fork, D. K., Chong, F. C., Mok, S., Smith, D. L., Swiatowiec, F, “Flexible Micro-Spring Interconnects for High Performance Probing,” Proceedings of the Electronic Components and Technology Conference, 2000, pp. 1157-1163.—Spring contacts.
[12] H. Han, E. L. Weiss and M. L. Reed, “Design and Modelling of a Micromechanical Surface Bonding System,” International Conference on Solid-State Sensors and Actuators, San Francisco, Calif., 1991, pp. 974-977.—MEMS Velcro.
[13] H. Han, L. E. Weiss and M. L. Reed, “Micromechanical Velcro,” in Journal of Microelectromechanical Systems, vol. 1, no. 1, pp. 37-43, March 1992.—MEMs Velcro
[14] M. S. Bakir, H. A. Reed, P. A. Kohl, K. P. Martin and J. D. Meindl, “Sea of leads ultra high-density compliant wafer-level packaging technology,” 52nd Electronic Components and Technology Conference 2002. (Cat. No. 02CH37345), San Diego, Calif., USA, 2002, pp. 1087-1094.—Large scale high density springs.

There remains a need for an easy way to manufacture interlocking structures that allows reworkable electrically conductive die bonding at fine pitch, low force, and low temperature.

### SUMMARY

This presentation discloses a metallic interlocking structure that provides a scalable, re-workable electrically conductive die bonding at fine pitch, requiring low force, and low interlocking process temperature.

This presentation discloses a nano/micro-scale electrically-conductive interlocking structure that can be made using a new combination of standard IC manufacturing process steps which 1) is low resistance, 2) is mechanically-compliant, 3) allows for “bonding” both mechanically and electrically some circuit pads (or bumps) without heat and with minimal application force (⅕ of a standard thermo-compression bonding), and 4) can be re-worked or re-used multiple times.

Embodiments of the interlocking structure according to this presentation comprise microstructures arranged in an array to form an electrically conductive interlocking structure capable of being interlocked with a corresponding (e.g. identical or complementary) electrically conductive interlocking structure according to this presentation. This presentation thus effectively allows electrically and mechanically bonding together two surfaces provided each with one of said electrically conductive interlocking structures. According to this presentation, the “bonding” of two interlocking structures together can be done at room temperature and allows creating an electrical contact between two integrated circuits connected each to one of the electrically conductive interlocking structures. Further, the bond can be physically removed in a non-destructive manner by pulling the two interlocking structures apart and both integrated circuits can for example be connected to other integrated circuits having compatible electrically conductive interlocking structures. Such possibility of reworking (un-bonding, re-bonding) an integrated component having an integrated circuit with electrically conductive interlocking structures according to this presentation is useful for e.g. testing and filtering yielding parts. Depending on the friction force exerted by the interlocking structures on each other, the bond between two interlocking structures according to this presentation can either be re-workable or permanent.

Embodiments of this presentation provide for an integrated component having a metallic interlocking structure; the integrated component having: an integrated circuit integrated in a substrate, the substrate having a top surface; the integrated circuit comprising a first conducting line; and a first metallic interlocking structure comprising a first array of free-standing metallic columns formed on said top surface.

According to an embodiment of this presentation, said free-standing metallic columns are electrically connected to said first conducting line.

According to an embodiment of this presentation, said first array of free-standing metallic columns is arranged such that introducing said columns, along an axis of said columns, between the columns of a second array of free-standing metallic columns having dimensions of a same order as the first array brings the columns of the two arrays in frictional contact and temporarily attaches the first and second arrays.

According to an embodiment of this presentation, said free-standing metallic columns have each a diameter smaller than two micrometers and are distant from each other (center to center) by at most 10 micrometers. According to an embodiment of this presentation, said free-standing metallic columns have each a diameter smaller than one micrometer and are distant from each other (center to center) by at most 5 micrometers.

According to an embodiment of this presentation, at least one free-standing metallic column has a top portion with a dimension, normal to an axis of said column, larger than a base of said column.

According to an embodiment of this presentation, a horizontal metallic beam connects the top of at least two neighboring free-standing metallic columns.

According to an embodiment of this presentation, the integrated component comprises a second conducting line that is distinct from said first conducting line; and a second metallic interlocking structure comprising a second array of free-standing metallic columns, formed on said top surface and electrically connected to said second conducting line.

Other embodiments of this presentation provide for an integrated component assembly comprising: a first integrated component as recited above; and a second integrated component as recited above, arranged upside down such that the first metallic interlocking structure of the second integrated component interlocks with the first metallic interlocking structure of the first integrated component.

According to an embodiment of this presentation, the friction between the lengths of the columns of the second integrated component with the lengths of the columns of the first integrated component maintains the first and second integrated components removably attached to each other.

According to an embodiment of this presentation, at least some columns of one of the first and second integrated components have a top portion larger than their base; and the friction of said larger top portions with the lengths of the columns of the other of the first and second integrated components maintains the first and second integrated components removably attached to each other.

Other embodiments of this presentation provide for a method of manufacturing an integrated component having a metallic interlocking structure; the method comprising: providing an integrated component having a substrate with a top surface and having an integrated circuit integrated in said substrate, the integrated circuit comprising a first conducting line; and forming on said top surface a first metallic interlocking structure comprising a first array of free-standing metallic columns.

According to an embodiment of this presentation, said forming on said top surface a first metallic interlocking structure comprising a first array of free-standing metallic columns comprises electrically connecting said metallic columns to said first conducting line.

According to an embodiment of this presentation, the method comprises dimensioning said first array of free-standing metallic columns such that introducing said columns, along an axis of said columns, between the columns of a second array of free-standing metallic columns having dimensions of a same order as the first array brings the columns of the two arrays in frictional contact and temporarily attaches the first and second arrays.

According to an embodiment of this presentation, the method comprises forming said free-standing metallic columns each with a diameter smaller than two micrometers; and comprises forming said free-standing metallic columns distant from each other by at most 10 micrometers. According to an embodiment of this presentation, the method comprises forming said free-standing metallic columns each with a diameter smaller than one micrometer; and comprises forming said free-standing metallic columns distant from each other by at most 5 micrometers.

According to an embodiment of this presentation, the method comprises forming at least one free-standing metallic column with a top portion having a dimension, normal to an axis of said column, larger than a base of said column.

According to an embodiment of this presentation, the method comprises forming a horizontal metallic beam that connects the top of at least two neighboring free-standing metallic columns.

According to an embodiment of this presentation, said integrated circuit comprises a second conducting line; the method further comprising forming a second metallic interlocking structure comprising a second array of free-standing metallic columns on said top surface and electrically connected to said second conducting line.

According to an embodiment of this presentation, said forming on said top surface a first metallic interlocking structure comprising a first array of free-standing metallic columns electrically connected to said first conducting line provides for: depositing on said top surface a precursor metal layer electrically connected to said first conducting line; electroplating said precursor metal layer; forming on said electroplated precursor metal layer a column mask layer having recesses where the columns are to be formed; filling the recesses of the mask by electroplating; and removing the column mask.

According to an embodiment of this presentation, the method further comprises, after filling the recesses of the mask by electroplating and before removing the column mask: forming a column-top mask having recesses with a diameter larger than the column; depositing at the bottom of the recesses of the column-top mask a column-top precursor metal layer; electroplating said column-top precursor metal layer; filling the recesses of the column-top mask by electroplating; and removing the column-top mask.

According to an embodiment of this presentation, the method comprises manufacturing said metallic interlocking structure using steps compatible with the back-end-of-the-line process used for manufacturing the integrated circuit.

Although specific advantages have been enumerated above, various embodiments may include some, none, or all of the enumerated advantages. Additionally, other technical advantages may become readily apparent to one of ordinary skill in the art after review of the following figures and description.

### BRIEF DESCRIPTION OF THE DRAWINGS

For a more complete understanding of this presentation and its advantages, reference is now made to the following description taken in conjunction with the accompanying drawings, in which like reference numerals represent like parts:

FIG. 1 illustrates schematically an integrated component having an integrated circuit with a metallic interlocking structure according to an embodiment of this presentation.

FIGS. 2A and 2B illustrate the interaction of two interlocking structures according to an embodiment of this presentation.

FIG. 3 illustrates an embodiment of an interlocking structure according to this presentation.

FIG. 4 illustrates an embodiment of an interlocking structure according to this presentation.

FIG. 5 illustrates the interaction of two interlocking structures according to an embodiment of this presentation.

FIGS. 6A to 6C are pictures of interlocking structures according to three embodiments of this presentation.

FIG. 7 is a picture of an interlocking structure according to an embodiment of this presentation.

FIG. 8 is a picture of an interlocking structure according to an embodiment of this presentation.

FIG. 9 is a picture of an interlocking structure according to an embodiment of this presentation.

FIG. 10 is a picture of an interlocking structure according to an embodiment of this presentation.

FIG. 11 is a picture of an interlocking structure according to an embodiment of this presentation.

FIG. 12 is a picture of an interlocking structure according to an embodiment of this presentation.

FIG. 13 is a picture of a test device for a chip with an interlocking structure according to an embodiment of this presentation.

FIGS. 14A to 14F are pictures illustrating an exemplary use of a chip with an interlocking structure according to an embodiment of this presentation.

FIG. 15 is a diagram illustrating the connection electrical resistance for a chip with an interlocking structure according to an embodiment of this presentation.

FIG. 16 is a diagram illustrating the force necessary to interlock an interlocking structure according to an embodiment of this presentation.

FIG. 17 is a diagram comparing the interlocking force of an interlocking structure according to an embodiment of this presentation with the bonding force necessary for other structures.

FIGS. 18A to 18F illustrate a process for manufacturing a component with an interlocking structure according to an embodiment of this presentation.

FIGS. 19A to 191 illustrate a process for manufacturing a component with an interlocking structure according to an embodiment of this presentation.

### DESCRIPTION

It should be understood at the onset that, although example embodiments are illustrated below, the present technology may be implemented using any number of techniques, whether currently known or not. The present technology should in no way be limited to the example implementations, drawings, and techniques illustrated below. Additionally, the drawings are not necessarily drawn to scale.

A purpose of a metallic interlocking structure according to this presentation is to enable high performance interconnections between two chips, or between a chip and a board or wafer, while still allowing for chip replacement (2 functions that are typically mutually exclusive). According to embodiments of this presentation, the metallic interlocking structure is manufactured with processes compatible with integrated circuits fabrication and can therefore be readily implemented on semiconductor wafers, in particular without degrading the original circuit performance.

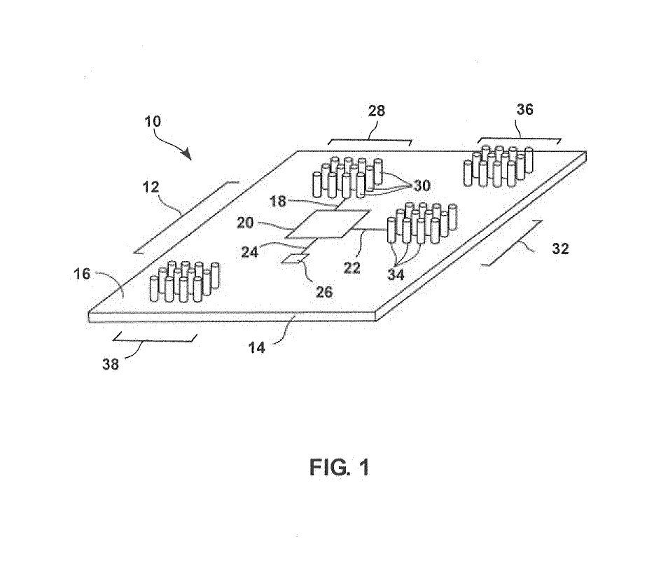

FIG. 1 illustrates schematically an integrated component 10 having a metallic interlocking structure according to an embodiment of this presentation; comprising an integrated circuit 12 integrated in a substrate 14 having a top surface 16; the integrated circuit 12 comprising a first conducting line 18. As schematically illustrated in FIG. 1, integrated circuit 12 can comprise a block 20 of integrated active or passive electronic elements having a number (3 shown) of input/output conducting lines 18, 22, 24. Integrated circuit 12 can further comprise a via 26 connecting top surface 16 to a bottom surface (not shown) of substrate 14; via 26 being connected to block 20 by a conducting line 24. According to an embodiment of this presentation, component 10 comprises a first metallic interlocking structure 28 comprising a first array of free-standing metallic columns 30 formed on the top surface 16 of substrate 14 and each electrically connected to said first conducting line.

According to an embodiment of this presentation, each free-standing metallic column 30 is a cylinder having a circular base. The base of the cylinder of each column 30 can also be elliptic or have any desired polygonal shape. According to an embodiment of this presentation, the diameter of the cylinder (or more generally, the largest lateral dimension of the column) is at least five times smaller than the height of each column 30.

According to an embodiment of this presentation, each column 30 has a diameter smaller than two micrometers and the columns are distant from each other by at most 10 micrometers. According to an embodiment of this presentation the columns 30 of array 28 are distant from each other such that another column of another array of columns of similar dimensions can only be introduced in between them by making frictional contact with the columns 30. For example, the array 28 of free-standing metallic columns 30 can be dimensioned such that introducing said columns 30, along said columns axis, between the columns of a second identical array (not shown) of free-standing metallic columns will bring the columns of the two arrays in frictional contact, thus temporarily attaching the first and second arrays.

According to an embodiment of this presentation, integrated circuit 12 comprises a second conducting line 22 distinct from first conducting line 18; and a second metallic interlocking structure 32 comprising a second array of free-standing metallic columns 34 formed on top surface 16 of substrate 14 and electrically connected to second conducting line 22. According to an embodiment of this presentation, any number of I/O pads of integrated circuit 12 can be connected to an array of columns such as illustrated with arrays 28 or 32.

As detailed hereafter, each array of columns such as 28, 32 can be used for implementing a removable connection to a corresponding array formed on a substrate to which integrated component 10 is to be attached, each array on said substrate being itself electrically connected to a circuit on the substrate to which integrated circuit 12 is to be connected. As detailed hereafter, an array of columns according to this presentation, such as 28, 32, can repeatedly be interlocked with, and unlocked from, a corresponding array of columns, wherein the frictional interaction of the arrays 28, 32 interlocked with the substrate arrays maintain component 10 attached to the substrate, thus advantageously replacing the use of non-permanent electrically conductive glues.

According to an embodiment of this presentation, component 10 can additionally or alternatively comprise one or more further arrays 36, 38, for example identical structurally to any of array 28, 32 but not connected to integrated circuit 12. Unconnected arrays 36, 38 can be arranged to interlock with corresponding unconnected arrays (not shown) on the substrate to which component 10 is to be attached, thus helping secure component 10 to the substrate by providing additional frictional interlocking between the component and the substrate. The unconnected arrays 36, 38 may further allow a better control of the growth of the other arrays 28, 32 by electroplating (detailed hereafter). The Inventors have noted that when only a small number of metallic interlocking structures is grown, if the current source used is not precise enough to send only the right amount of current, the growth of the metallic interlocking structures can be too fast and difficult to control. Growing additional metallic interconnecting structures helps reduce the current in each metallic interconnecting structure, thus making the growth of the metallic interconnecting structures by electroplating easier to control.

There are many exemplary applications for a component having an integrated interlocking structure according to this presentation:

For example, microfabricated 3D arrays featuring tiled architectures, in which multiple chips are bonded side-by side, tile-like, to form a large array. Should any of the individual chips in the array a) be misaligned, b) not perform well, and/or c) degrade over time, then, if they were attached to the array with the metallic interlocking structure according to this presentation, they could be removed and replaced. In contrast, tiled arrays currently assembled with state-of-the-art thermo-compression bonding are final. Any defects/degradation results in loss of the entire array. For such applications, a metallic interlocking structure according to this presentation provides significant cost savings with negligible interconnect performance trade-offs.

In traditional multi-chips modules (for example a 10 GHz Transmit and Receive module for phased array applications), multiple chips from diverse technologies are typically “die-attached” to a metal heat spreader/base board. Because each module is very expensive, integrators use reworkable glue to attach the chips. These glues (e.g., silver epoxy) have low thermal conductivity but allow for chip removal if the chip fails. Enabling replacement of a module chip if it fails saves an entire module. A metallic interlocking structure according to this presentation advantageously replaces and outperforms these conductive glues, providing as detailed hereafter conductive bonding performances comparable to the ones from permanent materials (e.g., eutectic solder), while being removable.

A metallic interlocking structure according to this presentation can enable high-performance testing of a chip having said structure on an advanced test board/wafer, by temporarily bonding the chip to said test board/wafer.

In addition, the Inventors have shown that a metallic interlocking structure according to this presentation can also be used to permanently bond chips using a room temperature process at low force. This is a significant advance over known thermo-compression bonding (au-au) or high-force room temperature indium bumping.

A metallic interlocking structure according to this presentation does not need an increased temperature to operate (no mismatch between materials with different coefficient of thermal expansion) and does not need high force (so one can do very large area bonding and assembly).

A metallic interlocking structure according to embodiments of this presentation allows for example to establish temporary electrical contacts for rapid prototyping, testing, and integration of technologies which would previously require labor-intensive processes and would either not be re-workable/non-permanent or would have poor electrical conductivity.

A metallic interlocking structure according to this presentation can also be scaled to produce bonding sites on the order of 5 micrometer by 5 micrometer, where the bonding-site pitch—center to center distance—can be as low as 10 micrometer. Generally speaking, the center to center distance between two bonding sites along a given direction can be twice the bonding site dimensions in the same direction; or can be larger; or can be lower, down to being the same as the bonding site dimensions in the same direction.

A metallic interlocking structure according to this presentation allows lowering costs for repairs since a component in a system-level package can be replaced if it is or becomes defective. Also, if a tested part is deemed good, additional force can be applied to make the bond permanent. Such additional force can for example push the interpenetrating column deeper, thus increasing the surfaces in contact of the various columns until the friction forces are so high that the component cannot be retrieved without being damaged.

Application in Infra-Red Focal Plane Arrays (FPAs): metallic interlocking structures according to this presentation can replace indium bonding and enable tighter pitches and lower cost for large-scale FPAs, enabling higher resolution images at higher yield (>5× improvement).

Advantageously, metallic interlocking structures according to this presentation also allow absorbing any Coefficient of Thermal Expansion (CTE) mismatch during system operation between a chip and a substrate to which the chip is attached, thus reducing the chances of damage due to such mismatch, thanks to bond compliance.

Application in millimeter wavelength phased arrays: metallic interlocking structures according to this presentation are a superior approach to flip-chip bonding (integration of SiGe chip with GaN PAs or LNAs) that allow reducing the cost associated with reworking/assembly (lowering cost by a factor of >5× due to re-work capability).

Application to integration of photonic or MEMS devices with silicon CMOS electronics: metallic interlocking structures according to this presentation can dramatically reduce assembly and rework costs, for example for chip-scale LIDAR such as those needed for autonomous driving and UAVs.

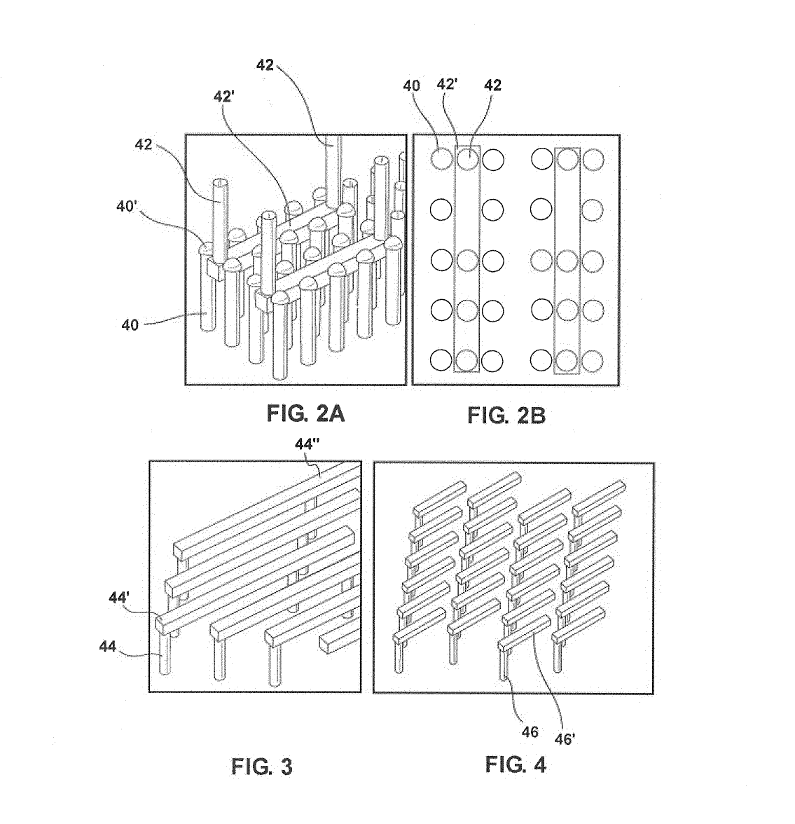

FIGS. 2A and 2B illustrate the interaction of two interlocking structures according to an embodiment of this presentation, comprising columns 40 that belong to an array of columns attached to a substrate (not shown) toward the bottom of FIG. 2A, and columns 42 that belong to an array attached to another substrate (not shown) toward the top of FIG. 2A. Thus, the columns 42 can be said to be upside-down relative the columns 40 and to the orientation of the arrays shown in FIG. 1. The arrays of columns illustrated in FIG. 1 schematically show uniform cylindrical columns. However, according to embodiments of this presentation, the columns can be non-uniform along their height. For example, the columns can have a uniform cross section along most of their height, up to a head/top of column portion of different cross section. The bottom part of FIG. 2A illustrates columns 40 having a uniform cross section up to a head portion 40′ of larger cross-section, thus giving each column a “pin” shape. According to embodiments of this presentation, the top portion of a column can have a parallelepiped shape developing in a direction normal to the axis of the columns. According to embodiments of this presentation, the top portion of two adjacent columns can be joined, so as to form a “loop” structure. The top portion of FIG. 2A shows the top portion 42′ of two adjacent columns 42 joined so as to form a “loop” structure, of an array according to an embodiment of this presentation, arranged upside-down and introduced in frictional contact between the columns 40.

FIG. 2B illustrates a top view of columns 40 and 42 as well as top portions 42′. According to an embodiment and as illustrated, top portions 42′ can have a dimension slightly smaller than the distance between two adjacent columns 40. According to an embodiment, the top portions 40′ (not shown in FIG. 2B) can be dimensioned such that top portions 42′ can barely pass between two adjacent top portions 40′.

FIG. 3 illustrates an embodiment of an interlocking structure according to this presentation, comprising columns 44 having rectangular parallelepiped top portions 44′ arranged such that: the top portions 44′ of two adjacent columns 44 are joined so as to form a “loop” structure; and at least one top portion 44′ develops in two directions from column 44, so as to form a “hook” structure 44″ on a side of the “loop” structure formed by two columns 44 and their joined top portions 44′.

FIG. 4 illustrates an embodiment of an interlocking structure according to this presentation, comprising columns 46 having rectangular prism/parallelepiped top portions 46′ developing all in a same direction normal to the axis of columns 46, so that each pair of a column 46 and its top portion 46′ forms a “hook” structure.

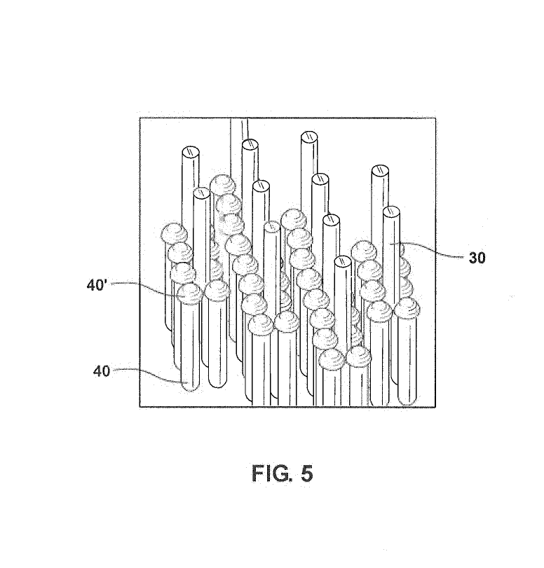

FIG. 5 illustrates the interaction of two interlocking structures according to an embodiment of this presentation. The bottom part of FIG. 5 shows “pin” shaped columns 40 having each a substantially spherical top portion 40′ having a diameter larger than the cross section of the column, interlocked with an upside-down array of uniform columns 30 such as illustrated in FIG. 1. The columns 30 can have the same areal density as the columns 40, or they can have a lesser areal density, as long as introducing the columns of one array between the columns of the other array creates frictional contact between the columns (or the top of the columns of one array and the columns of the other array). According to an embodiment of this presentation, as long as the “frictional contact” constraint is satisfied, the columns 30 can have different diameters and pitches than columns 40. Also, neither the array comprising columns 30 nor the array comprising columns 40 need be fully populated.

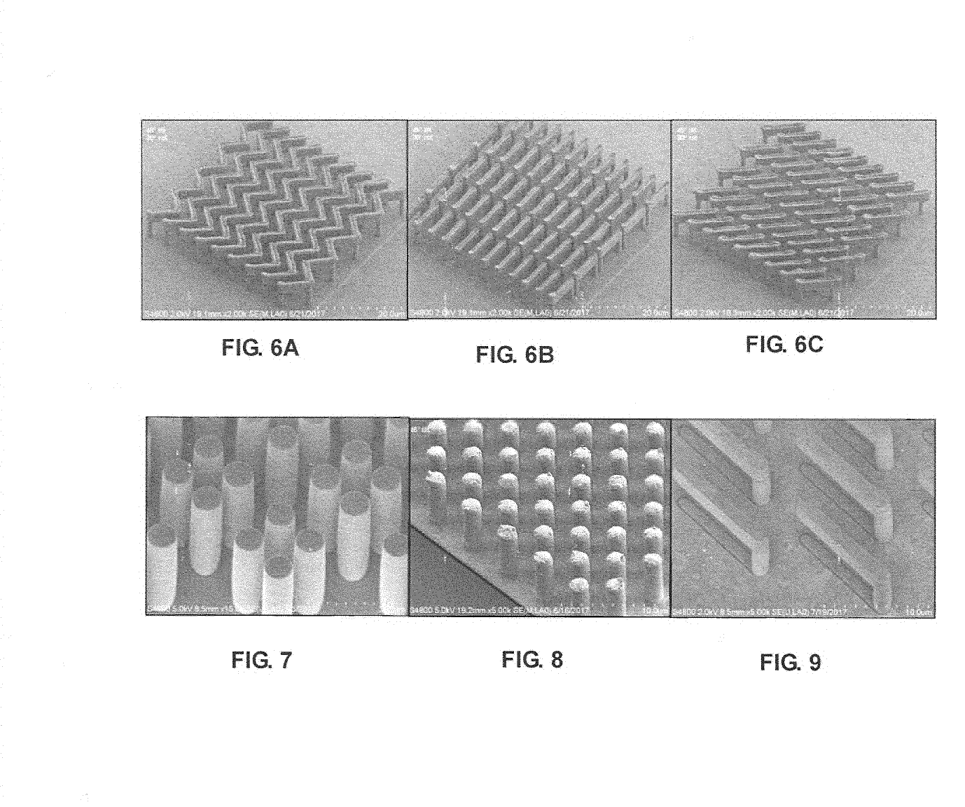

FIGS. 6A to 6C show SEM micrographs of fabricated metallic interlocking structures according to this presentation, wherein horizontal elements are formed between the top portions of neighboring columns, thus forming arrays of loops. Such arrays of loops are for example provided for frictionally engaging arrays of columns (simple columns as in FIG. 1; or pinhead-shaped column as in FIG. 5; or double-pinhead shaped as detailed hereafter; or with a bulging middle section as detailed hereafter. In the examples illustrated, the columns had a width/diameter from 0.5 to 4 micrometer and a column pitch ranging from <2 micrometer to 10 micrometer (the pitch being measured between the centers of two consecutive columns, the minimum pitch for columns having a diameter d is of 2d, preferably slightly above 2d). For example, the columns can have a diameter of 1 micrometer with 2 micrometer pitch. As shown in FIGS. 6A and 6B, the top portions of columns forming adjacent loops can be connected together so as to form series of loops attached together along straight lines or zig zag lines. As shown in FIG. 6c, the columns joined by their top portions can be arranged so as to form an array of adjacent individual loops.

FIG. 7 shows a SEM micrograph of an array of columns according to an embodiment of this presentation, where the columns have essentially a constant diameter and are arranged along a regular array of groups of four columns.

FIG. 8 shows a SEM micrograph of an array of columns according to an embodiment of this presentation, where the columns have essentially a constant diameter and are arranged along a regular array of columns, essentially as illustrated in FIG. 1.

FIG. 9 shows a SEM micrograph of an array of columns according to an embodiment of this presentation such as illustrated in FIG. 4, where a horizontal element wider than the column can be formed at the top of one or more of the columns, for example a horizontal element developing in a given direction from the top of each column so as to form a “hook” shape. According to embodiments of this presentation, the “hook” shape of the interlocking structure can be arranged to cooperate with a “loop” shaped interlocking structure as illustrated in e.g. FIG. 3 or 6a-c.

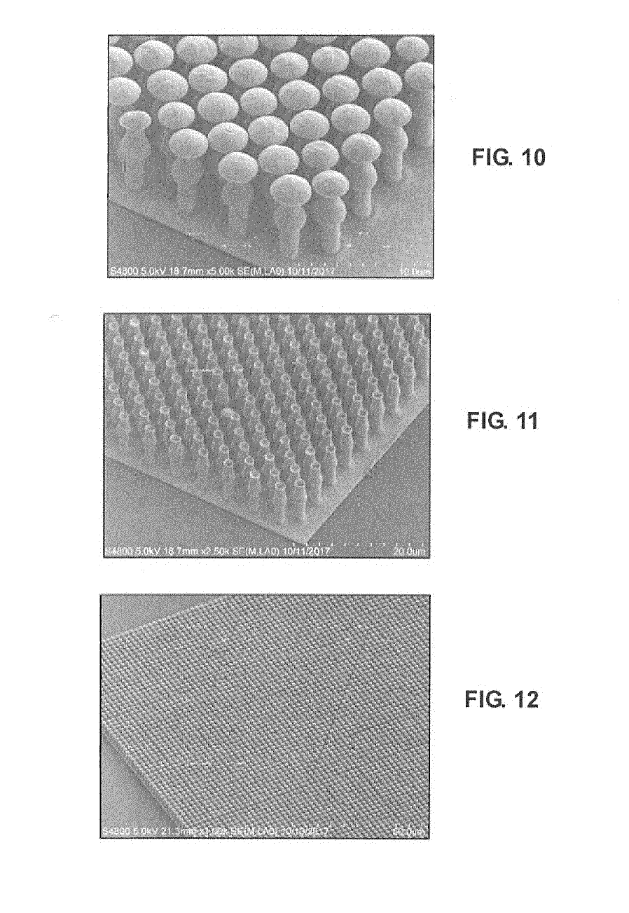

FIG. 10 shows a SEM micrograph of a fabricated metallic interlocking structure or column array according to this presentation, wherein each column comprises a pinhead shaped column formed on top of a pinhead shaped column.

FIG. 11 shows a SEM micrograph of column array according to this presentation, wherein each column comprises a bulging mid-section.

FIG. 12 shows a SEM micrograph of a fabricated metallic interlocking structures according to this presentation, wherein each column is essentially a simple cylinder. FIG. 12 shows that an array of columns according to embodiments of this presentation can comprise a large number of columns, for example 70 by 70 columns with a pitch of 25 μm, forming an array of 1.75 by 1.75 mm.

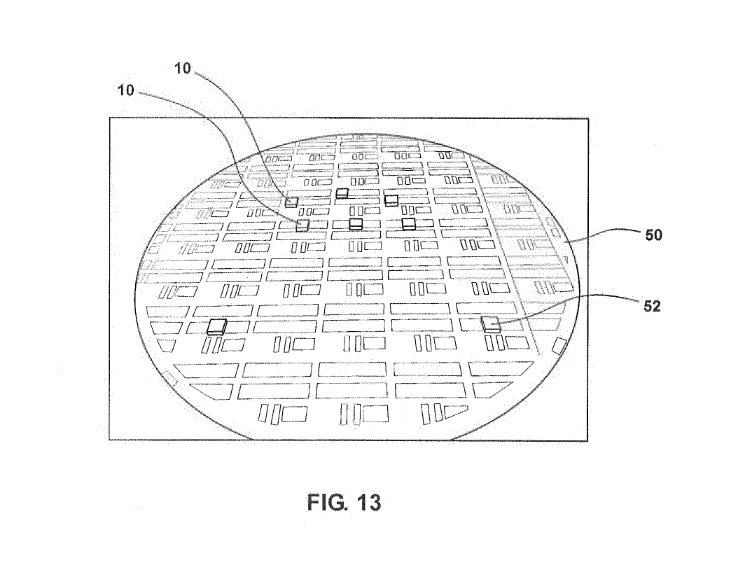

FIG. 13 is a photograph of a test device for integrated components 10 with an interlocking structure according to an embodiment of this presentation. A silicon wafer 50 was manufactured, which comprises a test integrated circuit having a plurality of integrated interlocking structures arranged for interlocking with the columns array (e.g. 28, 32, 36, 38) of upside-down integrated components 10 as illustrated in FIG. 1. Test wafer 50 can be described as a wafer comprising a plurality of integrated components as shown in FIG. 1 that were not diced away after manufacturing. The components 10 were then attached to the wafer by positioning the components above the area where the components were to be attached, and the components were gently pressed down so that the column arrays of the component interpenetrate the columns arrays of the wafer, and the frictional contact between the columns of the arrays maintain the component attached to the wafer. For test purpose, additional test chips 52 identical to the components 10 but having known thermo-compression bond pads instead of column arrays were bonded with thermo-compression to other portions of the test wafer, also equipped with known thermo-compression bond pads instead of column arrays.

Embodiments of this presentation also include an integrated component assembly as illustrated in FIG. 13, comprising: a first integrated component as e.g. shown in FIG. 1; and a second integrated component 10 as recited in claim 1, arranged upside down such that the metallic interlocking structure of the second integrated component interlocks with the metallic interlocking structure of the first integrated component.

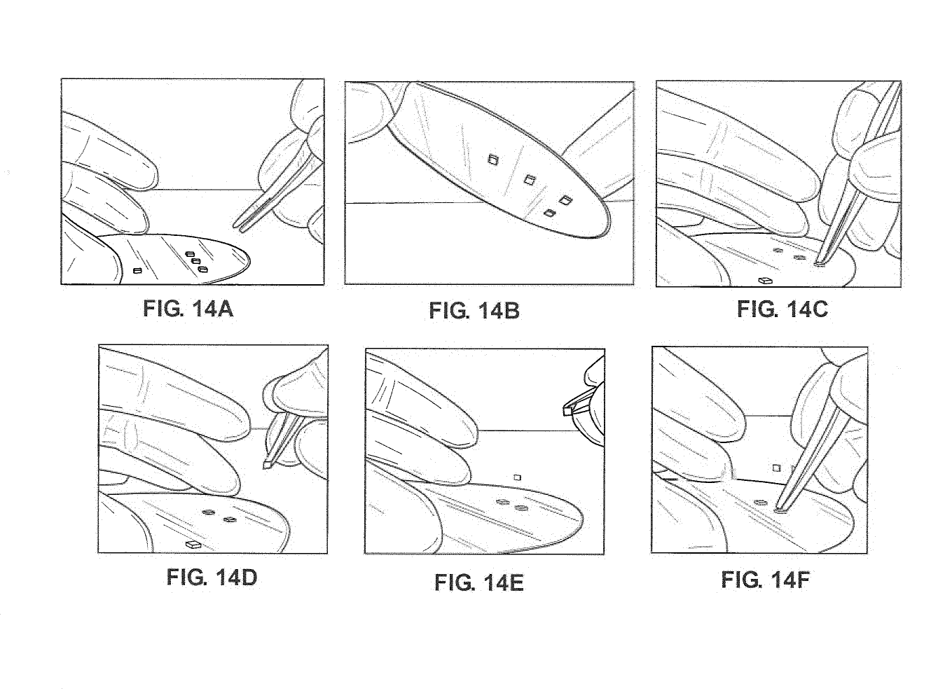

FIGS. 14A to 14F are pictures illustrating an exemplary use of the test wafer 50 of FIG. 13. FIG. 14A shows wafer 50 after all the test components 10 were placed on wafer 50 and gently pressed into attachment with tweezers. FIG. 14B shows a user shaking the wafer 50 without causing the test components to fall. At this juncture, the electrical connections of the wafer with each component 10 were tested, as illustrated hereafter. FIGS. 14C to 14E show a user removing the components 10, thus evidencing at least removability of a component according to an embodiment of this presentation after assembling said component to a wafer and validating the electrical connection of the component to the wafer. FIG. 14F shows a user checking that thermo-compression bound components cannot be separated from the wafer.

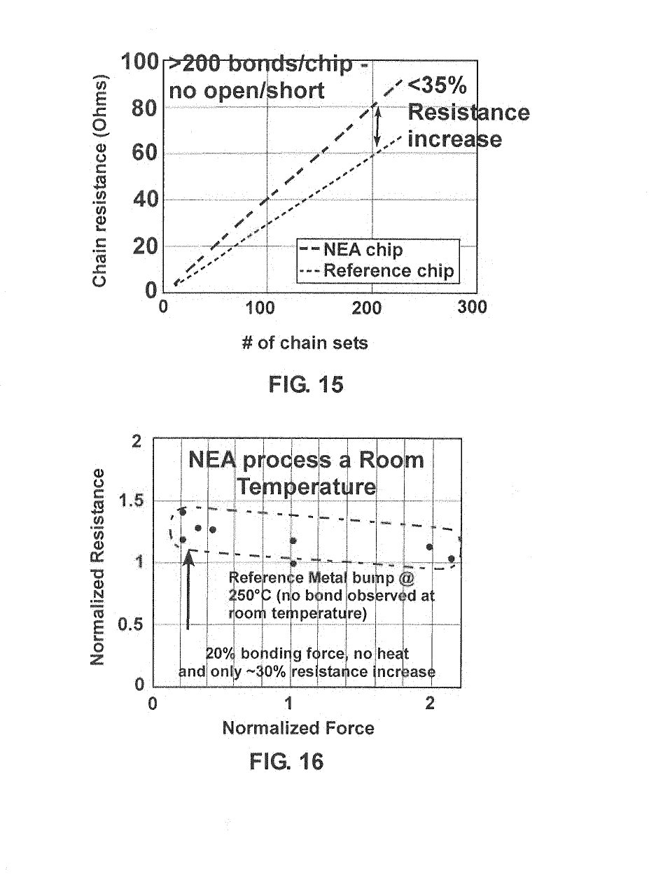

FIG. 15 is a diagram illustrating an example of DC resistance measurement from the test structures shown in FIG. 13 (data labeled “NEA chip”). The resistance of a thermo-compression assembly of two thermo-compression pads (using standard Au metal pads and thermo-compression bonded at 250° C. for 3 min and high force (for example 30 Kg per mm²); data labeled “Reference chip”) is 35% lower than the resistance of interlocked arrays of metallic columns according to this presentation chips assembled using a metallic interlocking structure according to this presentation. Further, test showed that components assembled using a metallic interlocking structure according to this presentation show a high bonding yield (>200 pads bonded without any shorts—two pads connected whereas they should not be- or opens—two pads not connected whereas they should be—).

FIG. 16 is a diagram that shows 4-point probe resistance measurement taken at various forces and temperatures. The measurements were performed at room temperature, and they were performed on structures bonded using different levels of normalized force. Structures bonded according to embodiments of this presentation were bonded at room temperature; thermo-compression bonding of a reference structure was performed at 250 C. The data (labeled “NEA process”) is normalized against the thermo-compression-attached reference chips. Test showed that chips assembled using a metallic interlocking structure according to this presentation enable using 20% only of the bonding force required for known thermo-compression processes, using no heat, and having only an increase in bonding resistance of approximately 30% the resistance of known thermo-compression processes.

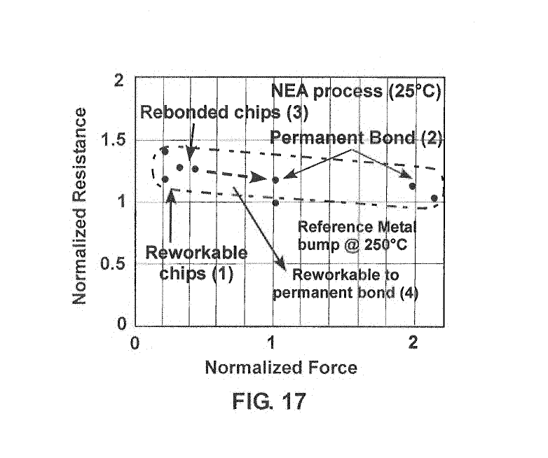

FIG. 17 is a diagram comparing the interlocking force of an interlocking structure according to an embodiment of this presentation with the bonding force necessary for other structures. FIG. 17 is a graph of normalized resistance versus the normalized force applied during bonding for an interlocking structure according to an embodiment of this presentation and for a thermo-compression-bonded structure. As illustrated by FIG. 17: 1/ Low-force interlocked components bearing circuits according to this presentation can be reworked (de-bonded or de-interlocked); 2/ High-force interlocked components bearing circuits according to this presentation could not be reworked (de-bonded or de-interlocked) manually; 3/ Re-used (re-interlocked) chips bearing circuits according to this presentation showed negligible degradation in electrical resistance (<10%); and 4/ A bonded re-workable component bearing a circuit according to this presentation can subsequently be bonded/re-interlocked permanently by applying more interlocking force (useful for functionality test prior to final assembly).

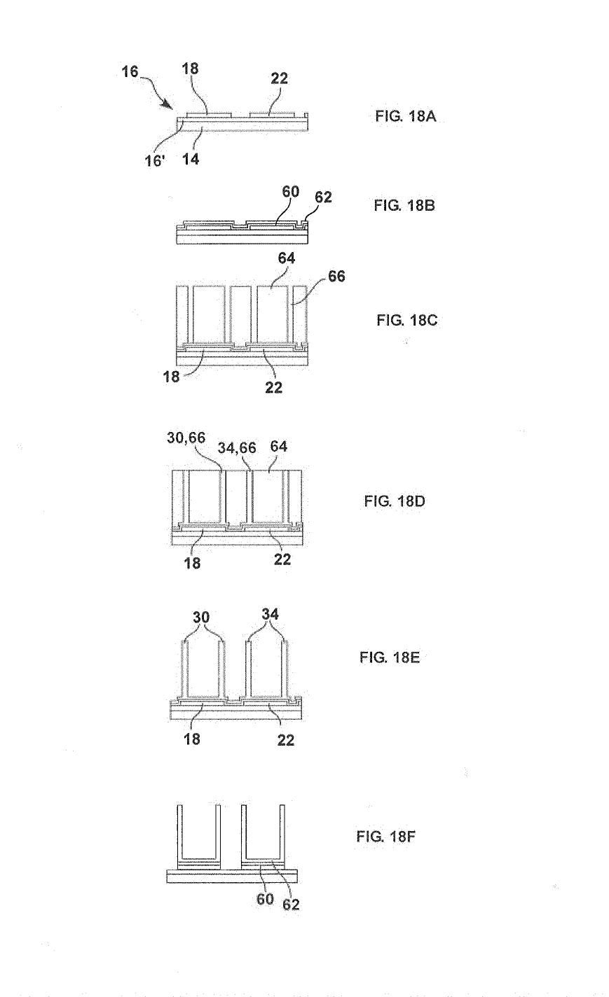

FIGS. 18A to 18F illustrate a process of manufacturing of a component with an interlocking structure according to an embodiment of this presentation. The figures illustrate in particular a process on a Si substrate 14, but it can be adapted to virtually any technology as the metal layers can be interchanged with other metals.

FIG. 18A illustrates a step comprising providing a substrate 14 having a top surface 16, wherein an integrated circuit 12 (not shown) is integrated in substrate 14 below an insulating dielectric top layer 16′, and wherein conducting lines 18, 22 connected to integrated circuit 12 are formed on top of dielectric layer 16′. It is noted that conducting lines 18, 22 are illustrated as being parallel to the surface of substrate 14. According to an embodiment of this presentation, at least one of lines 18, 22 can alternatively comprise a via extending from circuit 12 into substrate 14 normal to the surface of substrate 14. According to an embodiment of this presentation, at least one of lines 18, 22 can alternatively comprise a mix of conductors extending into substrate 14 parallel and normal to the surface of substrate 14.

FIG. 18B illustrates a step comprising depositing on top surface 16 of substrate 14 a precursor metal layer 60 electrically connected to conducting line 18 and 22; then forming on top of precursor layer 60 a thicker electroplated metal layer 62. Precursor layer 60 can be formed by metal evaporation or sputtering. It can comprise Ti/Au. According to an embodiment of this presentation, both layers 60 and 62 cover completely the area of surface 16.

FIG. 18C illustrates a step comprising forming on the electroplated metal layer 62 a column mask layer 64 having recesses 66 where the columns 30, 34 are to be formed. Mask 64 can be achieved by using a high aspect ratio patterning of a photoresist layer, which allows for creation of metallic pillars and pads (for example at least 5:1 aspect ratio with feature diameter <2 micrometer and/or pitch not exceeding 10 um—the pitch being measured as a pillar center to pillar center distance). According to an embodiment of this presentation, the diameter and pitch of the columns can be such that a second array of columns can be introduced between the columns of a first array, such that the friction between the columns of the first and second arrays maintains the two arrays engaged together, and such that a predetermined strength need be applied to separate the two arrays from each other. Such predetermined strength can be comparable to the strength needed to separate a chip package from a socket. Such predetermined strength must be sufficient for preventing the arrays from being separated by forces due to accelerations envisioned for the arrays in use (e.g. such as the acceleration due to a dropping on the ground of an apparatus using the array).

FIG. 18D illustrates a step that comprises forming the columns 30, 34 by filling the recesses 66 of the mask 64 by electroplating (for example using Au & Ni, or Pt and Cu). Embodiments of this presentation comprise forming narrow columns only or wide columns only or any mix of wide and narrow columns.

FIG. 18E illustrates a further step that comprises removal of photoresist mask 64; and FIG. 18F illustrates a further step that comprises removal of the plating membranes 60 and 62 where necessary (for example by protecting the pads with resist, removing the metal between the pads with dry of wet etching techniques, then removing the resist) to isolate the various column arrays from each other, maintaining the columns 30 of array 28 in contact with conducting line 18 and maintaining the columns 34 of array 32 in contact with conducting line 22, and isolating the columns (not shown) of arrays 36, 38 (not shown) from the other conductors on surface 16.

Advantageously, forming the columns by electroplating allows forming metallic columns having a very high aspect ratio (for example at least 5 times higher than they are wide). It is to be understood that the columns can be uniform, as illustrated for example in FIGS. 1, 7, 8, 12. Top portions of the column wider than the base of the column are optional. It is also to be noted that more than two electroplating masks can be used. For example, a further column mask can be used on top of a column-top mask to form a column having a middle section wider than its base and top sections, as illustrated in FIG. 11. Also for example, a further column-top mask can be used to form a “pinhead” column on top of a “pinhead” column, as illustrated in FIG. 10.

Advantageously, the fabrication steps illustrated in FIGS. 18A-18E can be implemented using process steps (metal layer sputtering, metal layer electroplating, mask forming and removal, localized metal etching) compatible with the back-end-of-the-line process used for manufacturing the integrated circuit. Thus, a metallic interconnecting structure comprising arrays of micrometer or sub-micrometer (e.g. 800 nm) scale columns according to embodiments of this presentation can be formed directly on the top surface of an integrated circuit chip as the last steps of the manufacturing process of the integrated circuit chip to allow flip-assembling the chip.

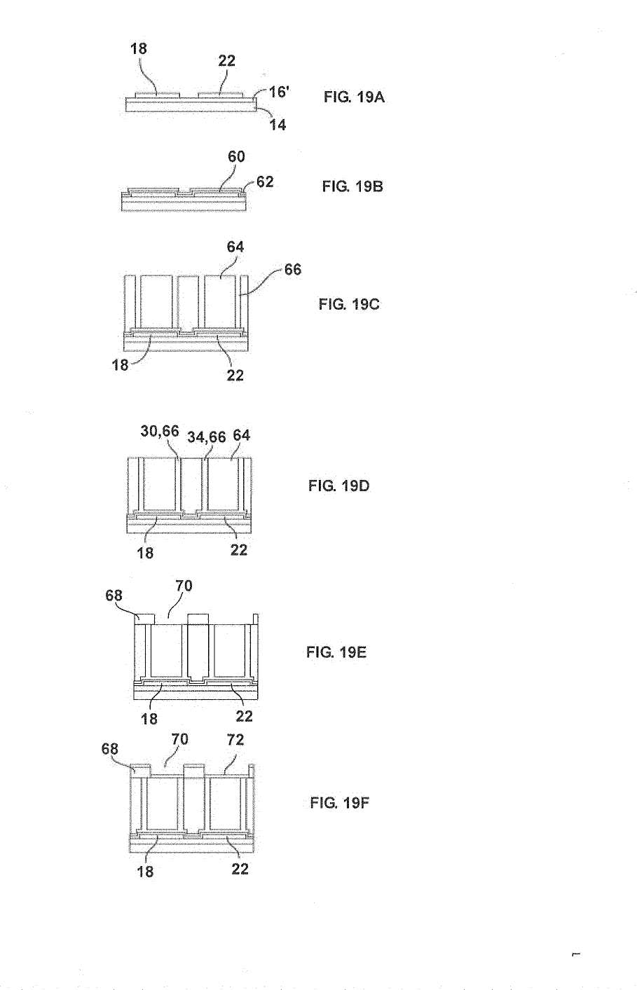

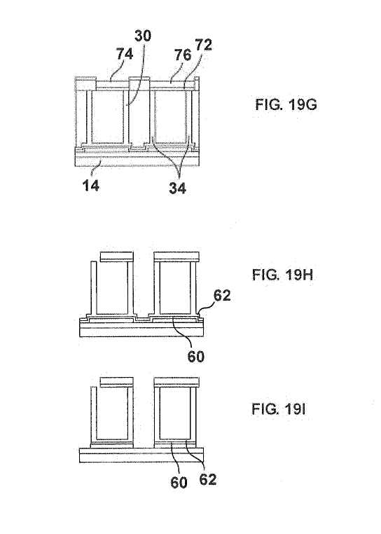

FIGS. 19A to 191 illustrate a process of manufacturing of a component with an interlocking structure according to an embodiment of this presentation, where the columns do not have a uniform diameter along all their length. FIGS. 19A to 19D are essentially identical to FIGS. 18A to 18D, as they allow forming arrays of columns 30, 34 having each a constant diameter on surface 16 of substrate 14, in contact with both conducting lines 18 and 22.

FIG. 19E illustrates a step that comprises forming a column-top mask 68 having recesses 70 where column tops wider than the column base/diameter are to be formed. As detailed above, a column top wider than the column diameter can be used to form a “hook” shaped column as well as a “pin” shaped column, or to join two columns to form a “loop” shape.

FIG. 19F illustrates a step that comprises depositing at the bottom of the recesses 70 of the column-top mask 68 a column-top precursor metal layer 72, for example by depositing an evaporated plating membrane (for example using Ti/Au). A first resist mold can be used to define the plating region.

FIG. 19G illustrates a step that comprises forming column top portions 74, 76 by electroplating on top of the column-top precursor metal layer 72 in recesses 70 (for example using Au & Ni, or Pt and Cu; for example through a secondary resist mold). As illustrated, a column top portion 74 can develop parallel to the surface of substrate 14 from the top of a single column (30 in the figure) so as to form a “hook” structure. As also illustrated, a column top portion 76 can alternatively develop parallel to the surface of substrate 14 from the top of at least two columns (34 in the figure) so as to form a “loop” structure. According to an embodiment of this presentation, a column array comprising “hook” structures can be provided to interlock with a column array comprising “loop” structures. According to an embodiment of this presentation, a column array comprising “hook” or “loop” structures can be provided to interlock with a column array comprising “pin” structures as described hereabove.

FIG. 19H illustrates the step that comprises removal of all photoresist masks, and FIG. 19I illustrates the step that comprises removal of the plating membranes 60 and 62 where necessary to isolate the various column arrays from each other.

It is noted that the cross-section of the columns can be circular, square, rectangular, ellipsoid, triangular, or have any shape appropriate such that a first array of columns according to an embodiment of this presentation develops a predetermined friction with an interlocking second array of columns according to an embodiment of this presentation.

Embodiments of this presentation provide for room temperature bondable metal contacts that are de-bondable and re-useable on a micro-scale.

Embodiments of this presentation provide for the fabrication of high density pillar arrays for mechanical and electrical structures such as interconnects, contact pads, solder bumps (as dense as e.g. 0.8 micrometer pillars with 2 micrometer pitch).

Embodiments of this presentation provide for making temporary/re-workable bonds permanent with the addition of additional force at temperatures from 22° C.+ and up to 150° C.

Embodiments of this presentation provide for distance between columns about the diameter of the columns.

The foregoing Detailed Description of exemplary and preferred embodiments is presented for purposes of illustration and disclosure in accordance with the requirements of the law. It is not intended to be exhaustive nor to limit the invention to the precise form(s) described, but only to enable others skilled in the art to understand how the invention may be suited for a particular use or implementation. The possibility of modifications and variations will be apparent to practitioners skilled in the art. No limitation is intended by the description of exemplary embodiments which may have included tolerances, feature dimensions, specific operating conditions, engineering specifications, or the like, and which may vary between implementations or with changes to the state of the art, and no limitation should be implied therefrom. Applicant has made this presentation with respect to the current state of the art, but also contemplates advancements and that adaptations in the future may take into consideration of those advancements, namely in accordance with the then current state of the art. Reference to a feature element in the singular is not intended to mean “one and only one” unless explicitly so stated. Moreover, no element, component, nor method or process step in this presentation is intended to be dedicated to the public regardless of whether the element, component, or step is explicitly recited in this presentation. No element disclosed herein is to be construed under the provisions of 35 U.S.C. Sec. 112, sixth paragraph, unless the element is expressly recited using the phrase “means for . . . ” and no method or process step herein is to be construed under those provisions unless the step, or steps, are expressly recited using the phrase “comprising the step(s) of . . . .”

1. An integrated component having a metallic interlocking structure; the integrated component comprising:
an integrated circuit integrated in a substrate having a top surface; the integrated circuit comprising a first conducting line; and
a first metallic interlocking structure comprising a first array of free-standing metallic columns formed on said top surface.

2. The integrated component of claim 1, wherein said free-standing metallic columns are electrically connected to said first conducting line.

3. The integrated component of claim 1, wherein said first array of free-standing metallic columns is arranged such that introducing said columns, along an axis of said columns, between the columns of a second array of free-standing metallic columns having dimensions of a same order as the first array brings the columns of the two arrays in frictional contact and temporarily attaches the first and second arrays.

4. The integrated component of claim 1, wherein said free-standing metallic columns have each a diameter smaller than two micrometers and are distant from each other by at most 10 micrometers.

5. The integrated component of claim 1, wherein at least one free-standing metallic column has a top portion with a dimension, normal to an axis of said column, larger than a base of said column.

6. The integrated component of claim 1, wherein a horizontal metallic beam connects the top of at least two neighboring free-standing metallic columns.

7. The integrated component of claim 2, comprising a second conducting line distinct from said first conducting line; and
a second metallic interlocking structure comprising a second array of free-standing metallic columns formed on said top surface and electrically connected to said second conducting line.

8. An integrated component assembly comprising:
a first integrated component as recited in claim 1; and
a second integrated component as recited in claim 1, arranged upside down such that the first metallic interlocking structure of the second integrated component interlocks with the first metallic interlocking structure of the first integrated component.

9. The integrated component assembly of claim 8, wherein the friction between the lengths of the columns of the second integrated component with the lengths of the columns of the first integrated component maintains the first and second integrated components removably attached to each other.

10. The integrated component assembly of claim 8, wherein at least some columns of one of the first and second integrated components have a top portion larger than their base; and wherein the friction of said larger top portions with the lengths of the columns of the other of the first and second integrated components maintains the first and second integrated components removably attached to each other.

11. A method of manufacturing an integrated component having a metallic interlocking structure; the method comprising:
providing an integrated component having a substrate with a top surface and having an integrated circuit integrated in said substrate, the integrated circuit comprising a first conducting line; and
forming on said top surface a first metallic interlocking structure comprising a first array of free-standing metallic columns.

12. The method of claim 11, wherein said forming on said top surface a first metallic interlocking structure comprising a first array of free-standing metallic columns comprises electrically connecting said metallic columns to said first conducting line.

13. The method of claim 12, comprising dimensioning said first array of free-standing metallic columns such that introducing said columns, along an axis of said columns, between the columns of a second array of free-standing metallic columns having dimensions of a same order as the first array brings the columns of the two arrays in frictional contact and temporarily attaches the first and second arrays

14. The method of claim 12, comprising forming said free-standing metallic columns each with a diameter smaller than two micrometers; and comprising forming said free-standing metallic columns distant from each other by at most 10 micrometers.

15. The method of claim 12, comprising forming at least one free-standing metallic column with a top portion having a dimension, normal to an axis of said column, larger than a base of said column.

16. The method of claim 12, comprising forming a horizontal metallic beam that connects the top of at least two neighboring free-standing metallic columns.

17. The method of claim 12, wherein said integrated circuit comprises a second conducting line;
the method further comprising forming a second metallic interlocking structure comprising a second array of free-standing metallic columns on said top surface and electrically connected to said second conducting line.

18. The method of claim 12 wherein said forming on said top surface a first metallic interlocking structure comprising a first array of free-standing metallic columns electrically connected to said first conducting line comprises:
depositing on said top surface a precursor metal layer electrically connected to said first conducting line;
electroplating said precursor metal layer;
forming on said electroplated precursor metal layer a column mask layer having recesses where the columns are to be formed;
filling the recesses of the mask by electroplating; and
removing the column mask.

19. The method of claim 18 further comprising, after filling the recesses of the mask by electroplating and before removing the column mask:
forming a column-top mask having recesses with a diameter larger than the column;
depositing at the bottom of the recesses of the column-top mask a column-top precursor metal layer;
electroplating said column-top precursor metal layer;
filling the recesses of the column-top mask by electroplating; and
removing the column-top mask.

20. The method of claim 12, comprising manufacturing said metallic interlocking structure using steps compatible with the back-end-of-the-line process used for manufacturing the integrated circuit.
